(19) United States
(12) Patent Application Publication
(10) Pub. No.: US 2008/0014661 A1
(43) Pub. Date: Jan. 17, 2008

(54) METHOD FOR THE MANUFACTURE OF SOLAR PANELS AND SPECIAL TRANSPORT CARRIER

(76) Inventors: Michael Haag, Rodenbach (DE); Michael Kaltenbach, Mainz-Kostheim (DE); Udo Kleemann, Stadecken-Elsheim (DE); Rainer Krause, Kostheim (DE); Douglas J. Murray, Brookfield, CT (US); Gerd Pfeiffer, Poughquag, NY (US); Markus Schmidt, Seibersbach (DE)

Correspondence Address: IBM MICROELECTRONICS;INTELLECTUAL PROPERTY LAW, 1000 RIVER STREET, 972 E, ESSEX JUNCTION, VT, 05452, US

(21) Appl. No.: 11/776,089

(22) Filed: Jul. 11, 2007

(30) Foreign Application Priority Data
Jul. 11, 2006 (DE) 06116972.8

(51) Int. Cl. H01L 21/00

(52) U.S. Cl. 438/4; 257/E21.002

(57) ABSTRACT

A method for the manufacture of solar panels from scrapped wafers and/or scrapped dies is provided, including the following steps: identifying scrap wafers and/or scrap dies; cleaning and removing remaining structures from the surface of the wafers/dies; grinding both surfaces of the wafers/dies down to a required thickness; doping the wafers/dies; and further processing the wafers/dies using a solar panel manufacturing method.

### CROSS REFERENCE TO RELATED APPLICATIONS

This application is related to German Patent Application No. 06116972.8, filed Jul. 11, 2006.

### FIELD OF THE INVENTION

The present invention relates in general to a method for the manufacture of solar panels. More specifically, the invention relates to a recycle process of semiconductor wafers and dies. In addition, the present invention is concerned with a special transport carrier used during the recycle process.

### BACKGROUND OF THE INVENTION

A solar panel is a flat collection of solar cells or solar thermal collectors used for converting solar energy into electricity or heat. The term “solar panel” can be applied to either solar hot water panels (usually used for providing domestic hot water) or solar photovoltaic panels (providing electricity). In the following, the main focus will be on solar photovoltaic panels.

A solar cell or photovoltaic cell is a semiconductor device consisting of a large-area p-n junction diode, which in the presence of sunlight is capable of generating usable electrical energy. This conversion is called the photovoltaic effect.

Solar cells have many applications. They are particularly well suited to, and historically used in, situations where electrical power from the grid is unavailable, such as in remote area power systems, handheld calculators, remote radiotelephones and water pumping applications. Solar cells (in the form of modules or solar panels) on building roofs can be connected through an inverter to the electricity grid in a net metering arrangement.

Various materials are being investigated for solar panels. Performance in the two main criteria, efficiency and costs, varies greatly. By far the most common material for solar cells is crystalline silicon. Crystalline silicon solar cells come in three primary categories:

Single crystal or monocrystalline wafers made using the Czochralski process;

Poly or multi crystalline wafers made from cast ingots; and

Ribbon silicon formed by drawing flat thin films from molten silicon and having a multicrystalline structure.

These technologies are wafer-based manufacturing. In other words, in each of the above approaches, self-supporting wafers between 180 to 240 micrometers thick are processed into solar cells and then soldered together to form a module. A wafer is a thin slice of semiconducting material, such as a silicon crystal, upon which microcircuits are constructed by doping (for example, diffusion or ion implementation), etching, and deposition of various materials. Wafers are thus of key importance in the fabrication of semiconductor devices. They are made in various sizes ranging from 1 inch (25.4 mm) to 11.8 inches (300 mm). Generally, they are cut from a boule of semiconductor using a diamond saw, then polished on one or both faces.

In the manufacturing of micro-electronic devices, die cutting or dicing is a process of reducing a wafer containing multiple identical integrated circuits to dice each containing one of those circuits. During this process, a wafer with up to thousands of circuits is cut into individual pieces, each called a die. In between the functional parts of the circuits, a thin non-functional spacing is foreseen where a saw can safely cut the wafer without damaging the circuit.

However, when manufacturing wafers and/or dies, scrap parts will occur due to contamination, physical damages, no functionality, yield criteria, etc. Due to the chemical substances used during processing, these scrap parts are actually treated as chemical waste for disposal. This, however, is a costly and complicated process.

Since raw material for solar cell manufacturers is short, there is a need for new solutions to increase the supply on a cost competitive level.

### SUMMARY OF THE INVENTION

It is therefore an object of the present invention to provide a method for the manufacture of solar panels that allows for providing raw panels on a cost competitive level.

It is another object of the present invention that these raw panels achieve the required specification limits for solar panels.

It is still another object of the present invention that disposal of the scrap parts during manufacture of semiconductor wafers and/or dies can be substantially reduced.

These and other objects and advantages are achieved by the method disclosed and the carrier disclosed.

Advantageous embodiments of the invention are also disclosed.

### BRIEF DESCRIPTION OF THE DRAWINGS

The invention will be described in more detail below in connection with the accompanying drawings, in which

FIG. 1 schematically shows an example of how to generate four solar panel plates out of a 300 mm scrap wafer;

FIG. 2 schematically depicts a generic process flow to create solar panels according to the invention;

FIG. 3 schematically illustrates the ionization process flow to ionize the Si material according to the invention;

FIGS. 4A and 4B schematically show a topview and a side view of a special die carrier for use according to the invention; and

FIG. 5 schematically shows a focused solar area device using parabolic mirror technology when using single silicon dies.

### DETAILED DESCRIPTION

As has already been mentioned above, shortage of raw material for solar cell manufacturers requires new solutions to increase the supply. In addition, a process has to be enabled which allows obtaining raw panels for solar cells on a cost competitive level. Furthermore, the new process, using semiconductor scrap wafers and dies, must assure that the required specification limits for solar panels are achieved.

The present invention provides a recycling process that is able to prevent disposal of scrap parts and related costs. The process can be used with 300 mm wafers as well as 200 mm wafers and, in addition, with all types of wafer dies. Thus, the inventive process is able to use scrapped wafers as well as sufficient large scrapped dies for photovoltaic solar element production.

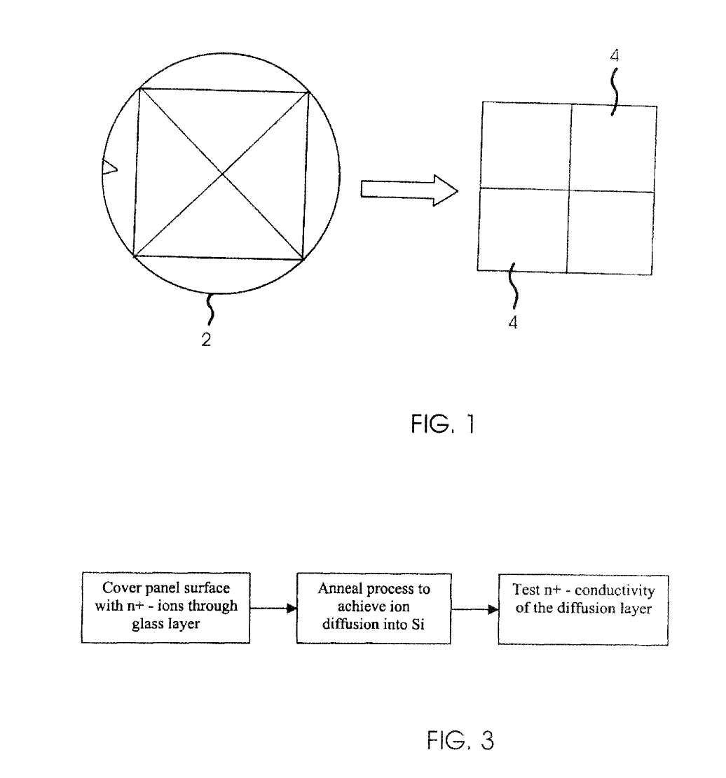

According to the invention, wafer scrap from 200 mm as well as 300 mm semiconductor manufacturing can be used to make square panels for solar cell production. As is shown in FIG. 1, in the case of a 300 mm wafer 2, the wafer is cut into quads 4. In the case of a 200 mm wafer, the wafer is cut into a single square (not shown). The single square normally has a maximum size of about 141×141 mm, and the respective squads show a maximum dimension of 106×106 mm. As can also been taken from FIG. 1, four scrap parts 8 will remain after cutting the wafer into the solar panel plates, however, the size of these scrap parts is clearly smaller than the whole wafer.

FIG. 2 schematically depicts a generic process flow to create solar panels according to the invention. First, the inventive solution for an entire wafer will be discussed.

Wafers are scrapped at several process steps throughout a wafer production line. Reasons for this are, e.g., physical damages, contamination, no functionality and yield criteria. Those wafers can be used in general for solar panel production unless they are broken. However, it is necessary that the scrap wafers will fulfill the specification criteria that are the prerequisites in order to be used as solar panels. These criteria are:

Wafer is not broken into pieces

Wafer is thicker than 300 μm

Wafer is 200 or 300 mm form factor

Test or product wafer

In a first step (200) wafers are identified as scrap fulfilling the above mentioned criteria. Wafers are scrapped in a semiconductor line according to existing rules and criteria, concerning yield and performance. These criteria are checked using measurement equipment for thickness, flatness and electrical performance. This can be done throughout the whole wafer production process. Normally, the scrap wafers typically go to a specific box and area for Non-Compliant Material (NCM). No specific handling is applied, the wafers might be physically damaged (broken). According to the invention, the scrap wafers are sorted into a wafer recycle box, whereby a better handling of the wafers is assured and physical damages are prevented. The wafer recycle box assures that the wafers are not stored with their surfaces attached to each other. The box can be similar to a Front Opening Shipping Box (FOSB) or to a Front Opening Unified Pad (FOUP), but does not require sealing to prevent contamination. This means that the wafers are kept in individual slots in order to keep them apart. The box material can be plastic or metal. No specific cleaning has to be applied to the boxes before reuse. The box may also be a simple box wherein the wafers are stored on top of each other with separating paper sheets between them. After the box is filled with scrap wafers, it is closed and may be marked with a bar code for traceability purposes. The box used for the scrap wafers should be able to be handled outside the manufacturing line, meaning that the box should be sealed, like a FOUP, to prevent the contents from additional particular and organic contamination. The sorted scrap wafers are moved out of the line within FOUPs, and then they are replaced into the recycle box mentioned above. The spacing between the wafers in the recycle boxes can be tighter as compared to conventional FOUP or FOSB boxes because the wafers will again be treated afterwards.

In a second step (202) the scrap wafers are cleaned with standard wet bench cleaning, and the remaining structures (integrated circuits) are taken off by etching of the structured surface. Etching can be performed by conventional methods like selective wet etch using an etch bath to remove the metallic layers deposited onto the wafer surface.

Next (Step 204), the wafers are grinded down to a thickness of 300 μm using conventional grinding machines to grind the silicon surface with high roughness, because no smooth surface is required. The wafer is placed on the grinder surface, fixed by a frame fitting the wafer size. The grinding is performed using a calibrated removal rate vs. time. Alternatively, the original thickness of 700 μm (the standard thickness for semiconductor wafers) is kept and only a front side contacting is applied, which has the advantage of using single contacting only instead of double side contacts. Thickness measurements are performed (Step 206) until the desired thickness of 300 μm has ben achieved. In case the required thickness has not yet been achieved, step 204 is repeated. The etching and grinding (lapping) processes are generating chemical waste for disposal (Step 208). The chemical waste contains certain metals which require a special treatment.

In step 210 the wafers are now laser cut into square panels for solar cell manufacturing. Scrap parts from cutting can be fed back to the wafer bulk material manufacturer.

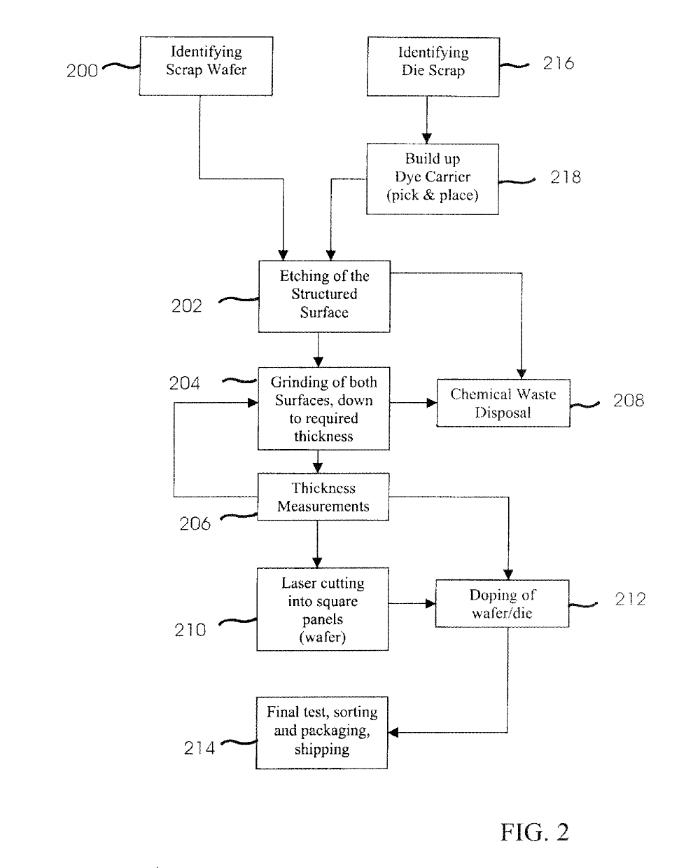

Following cutting, the square panels are treated in a print process to add a doping glass layer with a phosphorous content (Step 212). However, any other deposition process capable of placing the phosphor layer on top of the panels can be used. Followed by a furnace step, the attached doping glass layer causes the phosphor content to migrate into the Si-layer by diffusion. The diffusion length is determined by the energy used (maximum temperature) as well as the duration of the furnace process. The ionization process flow is given in FIG. 3.

Sometimes wafers are manufactured such that they show a high boron doping. This can be compensated for by using phosphorus doping to either reduce p-doping or even achieve n-doping. The doping process must be different in the case of a high p-doping on the wafer level. This requires a two-step process, namely neutralizing the high doping (˜10 Ωcm) in a first step and applying “regular” doping (0.5-2.5 Ωcm) in a second step in order to achieve the required p/n junction.

Finally, characterization of panels and supply to the customer takes place (Step 214) by final testing, packaging and shipping.

Doping is followed by front- and backside contacting, this being a conventional process used in solar panel manufacturing. Normally, this is achieved by using a printing method (Siebdruck) to place the contact pads.

In the following, the inventive solution for individual dies will be presented.

Wafer die scrap from semiconductor manufacturing can be used to make square panels for the solar cell production unless they are broken. Dies are scrapped after dicing in the wafer backend FIG. 2, Step 216). Reasons for this are, e.g., physical damages, contamination, no functionality, etc. As for the wafers, the dies should fulfill the following specification criteria:

Die is not broken into pieces

Die is thicker than 300 μm

Die has footprint of ≧100 mm²

Normally, the scrap dies, like the scrap wafers, go into a specific box and area for NCM. According to the invention, the scrap dies now go into a recycle box, thus assuring a better handling. No special care is required due to later treatment. Thus, the transport boxes can be simple plastic boxes.

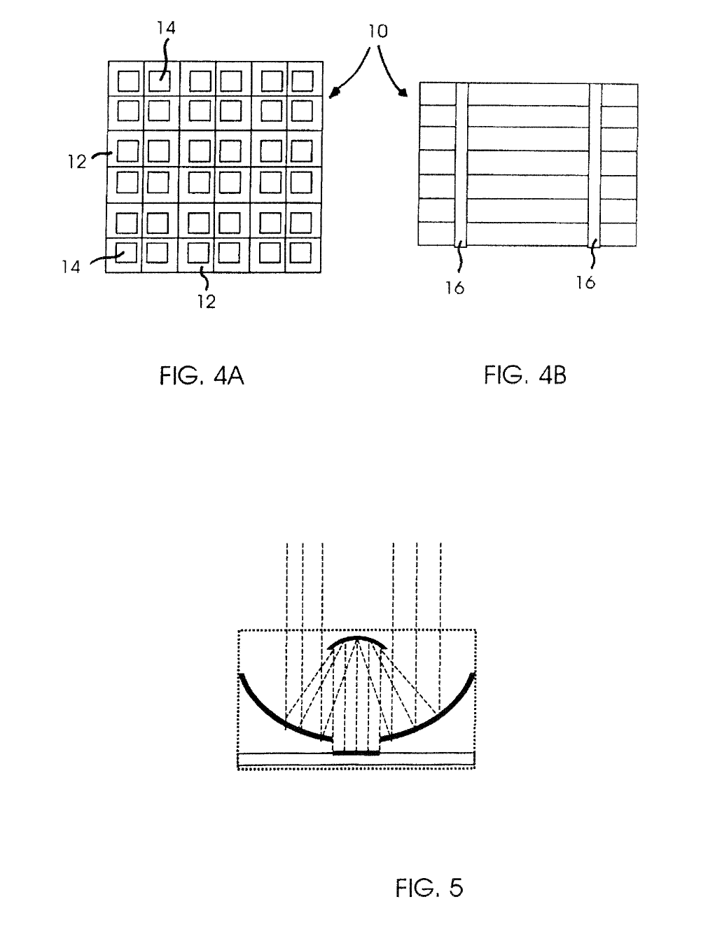

The finished dies require a specific metallic processing carrier (Step 218), assuring conductivity for the die backside. The special carrier should prevent the dies from being damaged. FIGS. 4A and 4B show a top view and a side view, respectively, of a possible carrier design. The carrier 10 is a flat plate with individual slots 12 for the scrap dies 14. This assures that the dies are not attached to each other. No specific cleaning has to be applied to the carrier before reuse. The carrier 10 is used to transport the scrap dies 14 to the solar cell recycling. Several carriers 10 can be put together, on top of each other, for transportation, fixed, e.g., with a rubber band 16. The spaces between the dies in the solar panel carrier 10 can be filled with any filling material (e.g., plastic) that fits into the material requirements. The dies 14 can be glued on the carrier 10, using an electrical contact glue. The process of placing the dies 14 on the carrier 10 can be performed using a conventional pick-and-place tool. The space filling can be done using polymer or soft metallic material (led type).

Next, the dies are cleaned and etched to remove the structure from the semiconductor process (Step 202; cf. FIG. 2)). For etching, all dies having the same size are put into an appropriate etch bath to etch off the structured layer besides copper, meaning acid based etching to take off the structured layers from the Si surface. To improve the etching, a brief grinding is applied to open the surface and make etching more efficient. Copper may remain on the dies to act as the conductive layer on the solar panel backside. Advantageously, processor dies should be primarily used, due to large footprints of typically ≧200 mm². However, other dies could be used as well. The dies must be placed on a conductive solar panel carrier or plate, which also can be used for further processing.

The former die front side, functional surface, now is the conducting backside of the solar unit, whereas the former die backside now is the active solar surface which has to be treated with n+-doping (Step 212, cf. FIG. 2) to enable photovoltaic functionality. The die solar panel carrier must be made of a metallic, and conductive material like steel (sheet metal) based, being able to sustain the n+-doping annealing process in the range of 800° C. The dies are placed on the carrier based on best fit to be able to place as much dies as possible on its surface. An example of loading such a solar panel carrier is shown in FIG. 5. In the case of dies having the dimensions 14×14 mm, used on a solar panel carrier of 100×100 mm, 49 dies can be placed with a spacing of 0.33 mm between them. In the case of dies having the dimensions 14×14 mm, used on a solar panel carrier of 135×135 mm, 81 dies can be placed with a spacing of about 1 mm between them.

Conductive soldering between the dies and the solar panel carrier surface is done during the n+-doping furnace process step.

As to the doping process itself, reference is made to the doping of wafers.

After doping is complete, characterization of panels and supply to the customer takes place (Step 214, cf. FIG. 2) by final testing, packaging and shipping.

As with the wafers, doping is followed by front- and backside contacting, this being a conventional process used in solar panel manufacturing. Normally, this is achieved by using a printing method (Siebdruck) to place the contact pads.

The quads (wafer and die panels) are now ready for regular solar panel treatment.

In the semiconductor line, the scrapped wafers and dies are handled using vacuum tweezers. The parts are sorted into the appropriate boxes and carriers without applying a specific cleaning, and shipped to the solar cell recycling.

In the solar process, the wafers can also be simply handled with vacuum tweezers, before as well as after dicing. The dicing can be carried out using a glass cutter (manual mode), for low volume, or a laser cutter for high volume. After the wafers have been prepared (etching and grinding/polishing) and cut into solar panels, the follow-on processes are those normally used in solar cell technology.

The dies are etched and grinded/polished. This is done in a carrier frame in the case of grinding/polishing. In the case of etching, the dies are collected in an etch basket. Die sorting into the final solar frame is carried out either with vacuum tweezers, in the case of low volume, or a pick and place machine, in the case of high volume.

When using dies, the photovoltaic effectiveness can be improved using not a full panel size, but focusing the illumination into a centre area. This is outlined in FIG. 5.

The device 18 shown there uses the effect of parabolic mirrors 20 to focus daylight or sunlight 22 on the centered solar device 24 containing only a few semiconductor dies manufactured by the inventive method, thus increasing the efficiency. The effect is that the solar cell output is increased using the higher light intensity. Also, the effect is that less solar cell surface is required to generate solar voltage. The small form factor of the individual die 24 enables any focus area size. To realize this with existing solar panels would require to cut the panel, which raises additional cost.

What is claimed is:

1. A method for the manufacture of solar panels from at least one of a scrapped wafer and a scrapped die, comprising the steps of:
a) identifying at least one of a scrap wafer and a scrap die;
b) cleaning and removing remaining structures from the surface of the wafer or die;
c) grinding both surfaces of the wafer die down to a required thickness;
d) doping the wafer or die; and
e) further processing the wafer or die using a solar panel manufacturing method.

2. The method of claim 1, wherein, when using at least one scrapped die, the die is mounted on a die carrier before the removing step.

3. The method of claim 2, wherein the carrier is a flat plate with an individual slot for each die.

4. The method of claim 1, wherein a scrap wafer or die is identified by monitoring at least one of thickness, flatness and electrical performance.

5. The method of claim 1, wherein cleaning of a wafer or die is carried out by wet cleaning.

6. The method of claim 1, wherein removing remaining structures is accomplished by etching.

7. The method of claim 6, wherein the etching comprises a selective wet etch.

8. The method of claim 1, wherein the grinding is carried out to a thickness of 300 μm.

9. The method of claim 1, wherein the wafer is laser cut into square panels after the grinding step.

10. The method of claim 1, wherein the wafer or die is n+-doped by adding a glass layer having a phosphorus doping content.

11. The method of claim 1, wherein the further processing includes frontside and backside contacting of the wafer or die.

12. The method of claim 11, wherein the frontside and backside contacting is carried out by using a printing method.

13. The method of claim 3, wherein the flat plate is made of a metallic and conductive material.

14. The method of claim 13, wherein said metallic and conductive material is steel.
